(19) United States
(12) Patent Application Publication
(10) Pub. No.: US 2005/0047106 A1
(43) Pub. Date: Mar. 3, 2005

(54) Substrate reinforcing in an LGA package

(76) Inventor: Peter Miguel Martino, Windham, NH (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/652,847

(22) Filed: Aug. 29, 2003

(51) Int. Cl. H05K 1/11; H05K 1/14

(52) U.S. Cl. 361/803

(57) ABSTRACT

Substrate reinforcement in a land grid array (LGA) package is provided. One embodiment is an LGA package for clamping to an interposer socket on a printed circuit board. One such LGA package comprises a substrate, a die attached to the upper surface of the substrate, a lid attached to the upper surface of the die, and a substrate reinforcement member attached to the upper surface of the substrate and separated from the lid.

### BACKGROUND

Currently, there are a variety of packaging technologies for designing and manufacturing various types of microelectronics assemblies (e.g., integrated circuit devices). In general, the microelectronics assembly is a sophisticated electrical/mechanical/thermal platform that comprises a package, a heat sink, and a printed circuit board. The package, which generally includes a die, a substrate, and a supporting lid, is connected to a printed circuit board. The heat sink is attached to the package for thermal management.

Land grid array (LGA) is one common form of microelectronics packaging. In LGA packaging, the electrical connection between the LGA package and the printed circuit board is established through pad-to-pad contact by clamping the LGA package to an interposer socket. The force required to clamp an LGA package may be, for example, as large as several hundred pound-force (lbf). This large clamping force may cause mechanical stress, deformation, or even cracking in the substrate. Further, in some LGA packaging, a relatively large differential can exist between the coefficients of thermal expansion (CTE) of the substrate material and the lid material. The CTE differential may also cause mechanical stress in the substrate material and/or the die-lid adhesive.

### SUMMARY

One embodiment of the present invention is an LGA package for clamping to an interposer socket on a printed circuit board. Briefly described, one such LGA package comprises a substrate, a die attached to the upper surface of the substrate, a lid attached to the upper surface of the die, and a substrate reinforcement member attached to the upper surface of the substrate and separated from the lid.

Another embodiment of the present invention comprises a method for reducing the mechanical stress in an LGA package comprising a substrate, a die attached to the upper surface of the substrate, and a lid attached to the upper surface of the die. Briefly described, one such method comprises reinforcing the substrate in the LGA package by attaching a support member to the upper surface of the substrate and separated from the lid.

### BRIEF DESCRIPTION OF THE DRAWINGS

Many aspects of the invention can be better understood with reference to the following drawings. The components in the drawings are not necessarily to scale, emphasis instead being placed upon clearly illustrating principles in accordance with exemplary embodiments of the present invention. Moreover, in the drawings, like reference numerals designate corresponding parts throughout the several views.

FIG. 1 is a cross-sectional view of an embodiment of an LGA package that employs a substrate reinforcement member attached to the upper surface of the substrate and separated from the lid.

FIG. 2 is an overhead view of the LGA package of FIG. 1.

FIG. 3 is an overhead perspective view of another embodiment of an LGA package illustrating another embodiment of a substrate reinforcement member.

FIG. 4 is an overhead perspective view of another embodiment of an LGA package illustrating a further embodiment of a substrate reinforcement member.

### DETAILED DESCRIPTION

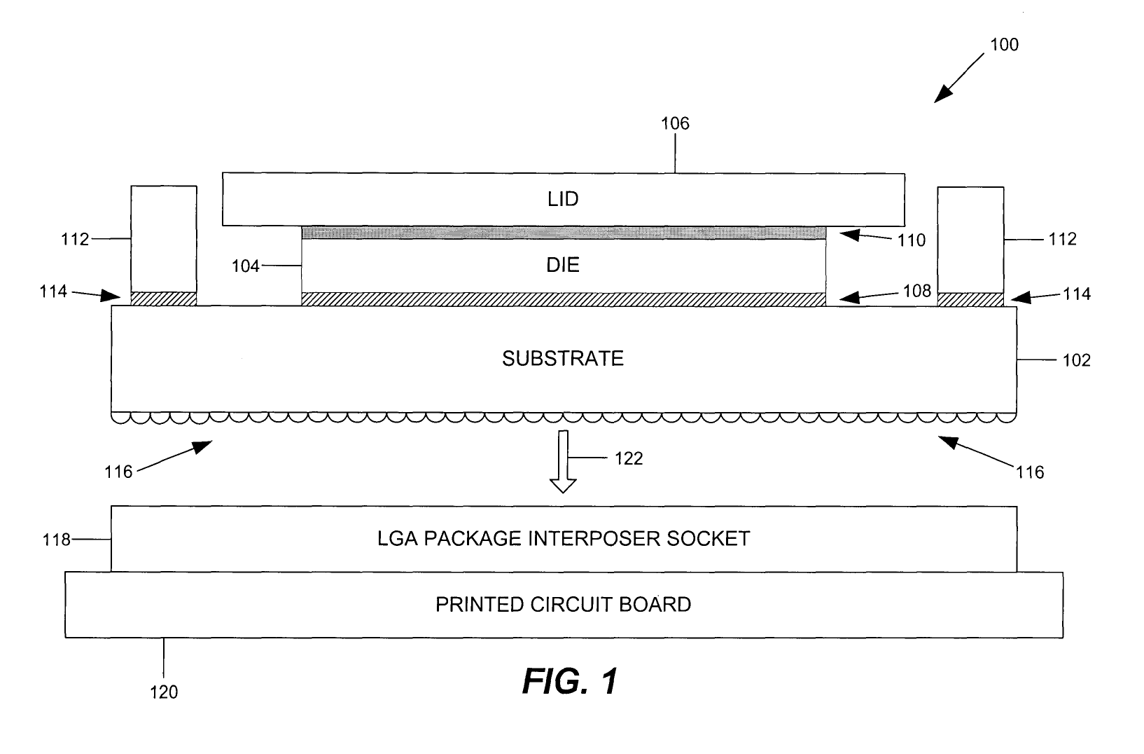

This disclosure relates to various embodiments of land grid array (LGA) packages in which substrate reinforcement member(s) are employed to reduce mechanical stress in the substrate and/or the adhesive material that attaches the package lid to the upper surface of the die. Several embodiments will be described below with reference to FIGS. 1-4. As an introductory matter, however, the basic configuration of an exemplary LGA package will be briefly described. It should be appreciated that substrate reinforcement member(s) may be attached to the upper surface of the substrate to reduce mechanical stress. The substrate reinforcement member(s) are not attached to the package lid. By separating the substrate reinforcement member(s) from the package lid, these components may be independently designed with appropriate thermal and mechanical properties.

The package lid material may be selected to provide desirable thermal performance. For example, the package lid may be made from materials having high thermal conductivity, such as AlSiC, CuW, SiC, etc. Although the package lid material may also have desirable mechanical properties, such properties may not be necessary because of the separate substrate reinforcement member(s).

The substrate reinforcement member(s) may be made from materials (e.g., Invar, SiC, etc.) having desirable mechanical properties to reduce mechanical stress in the substrate and/or lid-die adhesive resulting from clamping forces or thermal expansion as described above. Additionally, the coefficient of thermal expansion of the substrate reinforcement member(s) may be advantageously matched with the coefficient of thermal expansion of the substrate to reduce thermally induced stress. Because heat is conducted out of the die via the package lid (and not the substrate reinforcement member(s)), the thermal properties of the substrate reinforcement member(s) may be matched with the thermal properties of the substrate to reduce thermally induced stress. Furthermore, the separation of the substrate reinforcement member(s) from the package lid enables the package lid to move downward to accommodate any bending of the substrate.

Having described the basic configuration of an exemplary LGA package, several embodiments of substrate reinforcement member(s) will be described with respect to FIGS. 1-4. It should be appreciated that any number of substrate reinforcement member(s) may employed. Furthermore, the shape, size, orientation, material composition, etc. of the substrate reinforcement member(s) may also be varied.

FIG. 1 illustrates one embodiment of an LGA package 100 in which a substrate reinforcement member 112 is employed to reduce stress in the substrate 102 and/or the lid-die adhesive 110. As illustrated in FIG. 1, LGA package 100 includes a substrate 102, a die 104, and a package lid 106. Die 104 is attached to the upper surface of substrate 102 using an adhesive 108. Package lid 106 is attached to the upper surface of die 104 using an adhesive 110 (e.g., glue, a thermal compound, epoxy, etc.). Lid 106 may be made from a material (e.g., AlSiC, CuW, SiC, etc.) having high thermal conductivity to promote desirable thermal performance.

Substrate 102 may be made from a material (e.g., glass ceramic) that has desirable electrical properties.

LGA package 100 may be connected to a printed circuit board 120 by applying a clamping force (reference number 122) to LGA package 100. When LGA package 100 is properly aligned with an interposer socket 118, the clamping force causes a grid of contacts 116 on the lower surface of substrate 102 to engage with interposer socket 118.

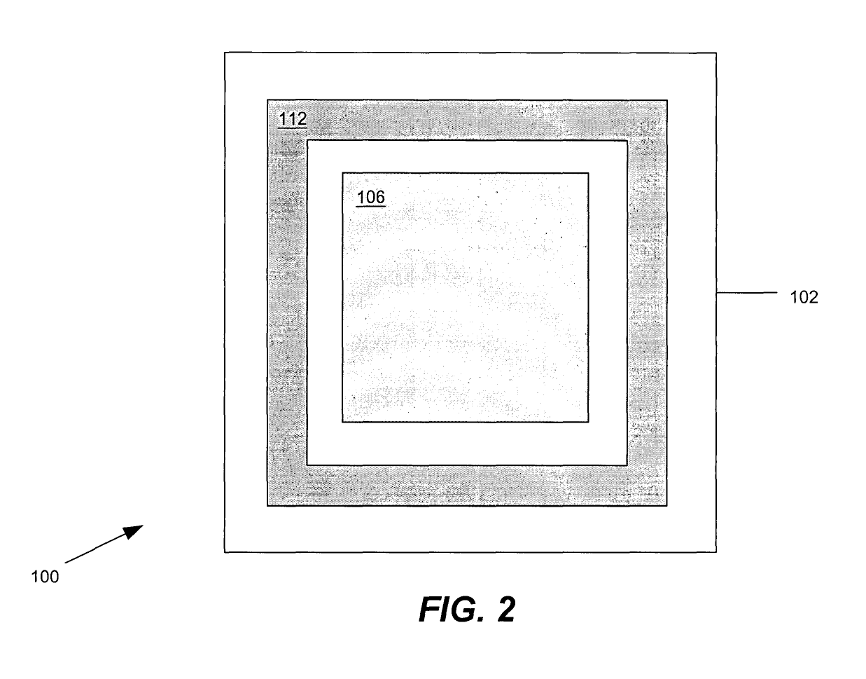

As best illustrated in FIGS. 1 and 2, substrate reinforcement member 112 comprises a square ring shape attached to the upper surface of substrate 102 with an adhesive 114. In side view or cross section (best shown in FIG. 1) substrate reinforcement member 112 can have a rectangular shape that extends upwardly from the substrate 102. The height of the member 112 can be approximately equal to the stacked height of the die 104 and lid 106. The substrate reinforcement member 112 can have different shapes and sizes as well. For example, the member 112 could have a circular or elliptical cross-section.

Substrate reinforcement member 112 is generally adjacent and parallel to sides of the lid 106. As shown in the exemplary embodiment of FIG. 2, substrate reinforcement member 112 extends along an outer periphery of lid 106 and follows the shape or contour of lid 106.

Substrate reinforcement member 112 may be made from a material having desirable mechanical properties to reduce mechanical stress in substrate 102 and/or lid-die adhesive 110 resulting from clamping forces or thermal expansion as described above. In certain embodiments, substrate reinforcement member 112 comprises a material such as Invar, SiC, etc. The coefficient of thermal expansion of substrate reinforcement member 112 may be matched with the coefficient of thermal expansion of substrate 102 to reduce thermally induced stress.

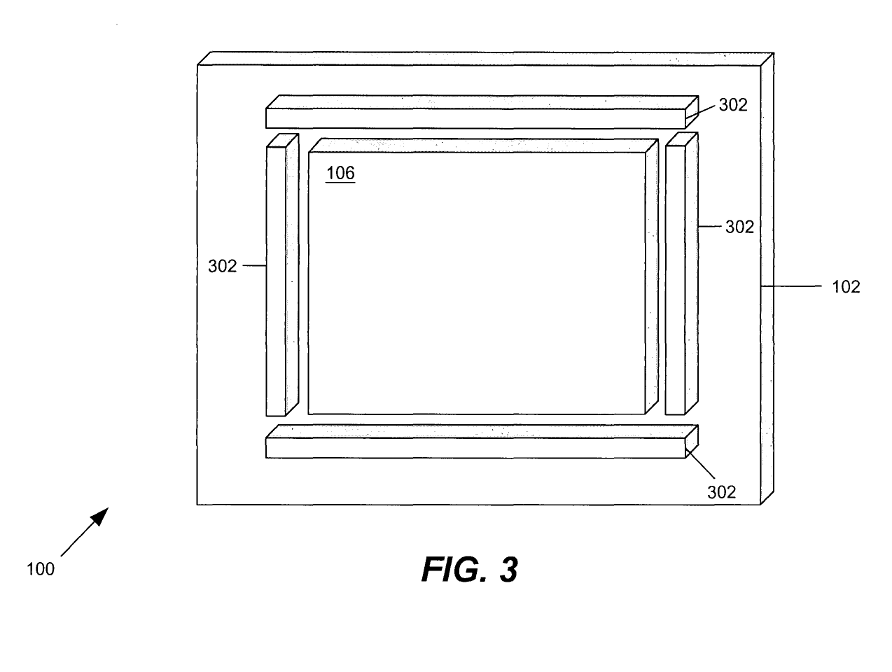

One of ordinary skill in the art will appreciate that substrate reinforcement member 112 may be configured in a number of alternative ways. For example, substrate reinforcement member 112 need not be a continuous member. As illustrated in FIG. 3, the substrate reinforcement member(s) may comprise two pairs of parallel longitudinal bar members 302 that are adjacent to and parallel with all sides of lid 106.

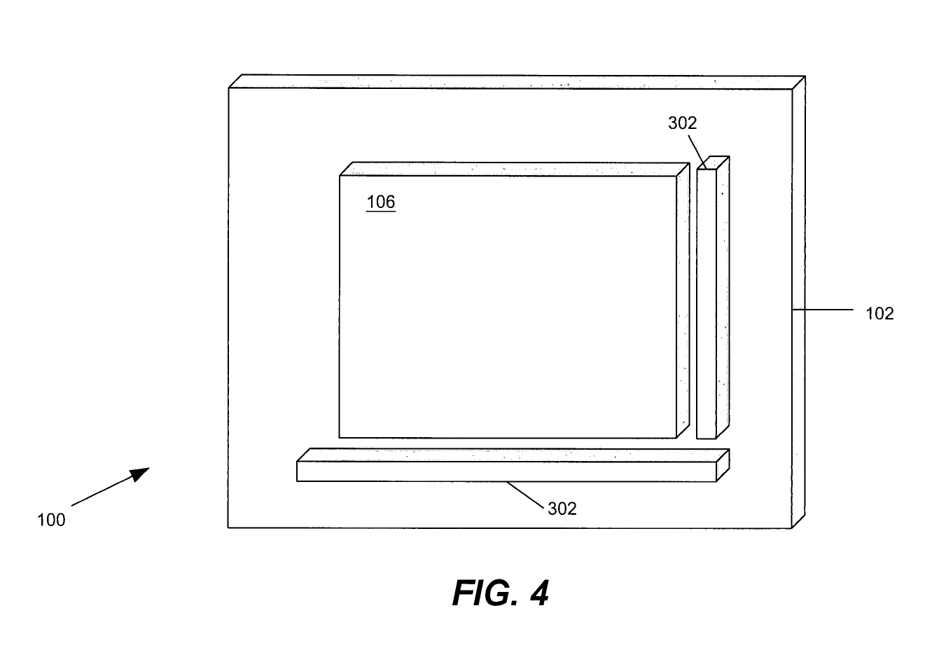

Other embodiments are also within the scope of the invention. For example, FIG. 4 illustrates LGA package 100 comprising only two longitudinal bar members 302 perpendicularly arranged to each other. These bar members 302 are adjacent to and parallel with two sides of lid 106.

1. A land grid array (LGA) package for clamping to an interposer socket on a printed circuit board, the LGA package comprising:
a substrate;
a die attached to an upper surface of the substrate;
a lid attached to an upper surface of the die; and
a substrate reinforcement member attached to the upper surface of the substrate and separated from the lid.

2. The LGA package of claim 1, wherein the substrate reinforcement member comprises a ring attached to the upper surface of the substrate around the periphery of the lid.

3. The LGA package of claim 1, wherein the substrate reinforcement member comprises at least one longitudinal bar.

4. The LGA package of claim 1, wherein the substrate reinforcement member comprises one of Invar and SiC.

5. The LGA package of claim 1, wherein the lid comprises one of AlSiC-9, CuW, and SiC.

6. The LGA package of claim 1, wherein a coefficient of thermal expansion of the substrate reinforcement member is substantially equal to a coefficient of thermal expansion of the substrate.

7. The LGA package of claim 1, wherein coefficients of thermal expansion of the substrate and the substrate reinforcement member are matched to reduce mechanical stress in the substrate and in an adhesive that attaches the lid to the upper surface of the die.

8. The LGA package of claim 1, wherein the substrate reinforcement member is parallel and adjacent to sides of the lid.

9. The LGA package of claim 1, wherein the substrate reinforcement member comprises four separate bars.

10. The LGA package of claim 1, wherein the substrate reinforcement member has an elongated bar shape.

11. In a land grid array (LGA) package comprising a substrate, a die attached to an upper surface of the substrate, and a lid attached to an upper surface of the die, a method for reducing the mechanical stress in the LGA package, the method comprising reinforcing the substrate in the LGA package by attaching a substrate support member to the upper surface of the substrate.

12. The method of claim 11, wherein the reinforcing the substrate in the LGA package further comprises matching a coefficient of thermal expansion of the substrate with a coefficient of thermal expansion of the substrate support member.

13. The method of claim 11, further comprising providing the substrate support member separated from the lid.

14. The method of claim 11, further comprising positioning the substrate support member around both the die and the lid.

15. The method of claim 11, further comprising providing the substrate support member as a continuous member extending around all sides of the lid.

16. A land grid array (LGA) package comprising:
a substrate;
a die attached to a surface of the substrate;
a lid attached to a surface of the die; and
a substrate reinforcement member attached to a surface of the substrate and being adapted to reduce mechanical stress in the substrate.

17. The LGA package of claim 16, wherein the substrate reinforcement member has a rectangular cross section.

18. The LGA package of claim 16, wherein the lid is adapted to move downwardly to accommodate bending of the substrate.

19. The LGA package of claim 16, wherein the substrate reinforcement member extends around a periphery of the die.

20. The LGA package of claim 16, wherein the substrate reinforcement member comprises two separate members that are adjacent to and separate from the lid.
